(19) United States
(12) Patent Application Publication
(10) Pub. No.: US 2009/0200072 A1
(43) Pub. Date: Aug. 13, 2009

(54) WIRING SUBSTRATE AND METHOD FOR MANUFACTURING THE SAME

(75) Inventor: Tomoo Yamasaki, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/366,166

(22) Filed: Feb. 5, 2009

(30) Foreign Application Priority Data
Feb. 8, 2008 (JP) 2008-029052

(51) Int. Cl. H05K 1/02; B05D 5/12

(52) U.S. Cl. 174/259; 427/97.4

(57) ABSTRACT

The wiring substrate 10 includes an insulating layer 13, a wiring 19, a bonding layer provided on such portion of the upper surface 13A of the insulating layer 13 as corresponds to the forming area of the wiring 19, and a seed layer 16 interposed between the bonding layer and wiring 19. The wiring substrate 10 further includes a Ni—Cu alloy layer 15 serving as the bonding layer.

### BACKGROUND OF THE INVENTION

The present invention relates to a wiring substrate and a method for manufacturing such wiring substrate. Specifically, the invention relates to a wiring substrate including a bonding layer interposed between a seed layer and an insulating layer, and a method for manufacturing such wiring substrate.

FIG. 1 is a section view of a conventional wiring substrate.

Referring to FIG. 1, a conventional wiring substrate 100 includes a substrate main body 101, a pad 102, an insulating layer 103, a CuN layer 105, a Cu layer 106, a wiring pattern 108, and a wiring 109.

The substrate main body 101 is a substrate on which the pad 102 and insulating layer 103 are to be provided. As the substrate main body 101, there can be used, for example, a build-up substrate with a core or a coreless substrate.

The pad 102 is provided on the upper surface 101A of the substrate main body 101. The pad 102 is electrically connected to a via and a wiring (neither of them is shown) which are to be provided on the substrate main body 101.

The insulating layer 103 is provided on the upper surface 101A of the substrate main body 101 and includes an opening 111 from which the upper surface of the pad 102 can be exposed. As the insulating layer 103, for example, there can be used an insulating resin layer.

The CuN layer 105 is provided not only on such portion of the surface of the insulating layer 103 and on such portion of the upper surface of the pad 102 that respectively correspond to the forming area of the wiring pattern 108 but also on such portion of the upper surface 103A of the insulating layer 103 as corresponding to the forming area of the wiring 109. The CuN layer 105 is a bonding layer which is interposed between the insulating layer 103 and Cu layer 106. The CuN layer 105 is a metal layer which can be removed using an etching solution for Cu.

The Cu layer 106 is arranged in such a manner that it covers the upper surface of the CuN layer 105. The Cu layer 106 is the power supply layer that is used when depositing and growing a plated membrane of which the wiring pattern 108 and wiring 109 can be formed.

The wiring pattern 108 includes a via 113 and a wiring 114 formed integrally with the upper portion of the via 113. The via 113 is provided on the Cu layer 106 that is formed in the opening 111. The wiring 114 is provided on the upper portion of the via 113 and also on the upper surface of the seed layer 106. As the material of the wiring pattern 108, there can be used, for example, copper (Cu). The above-structured wiring pattern 108 is electrically connected to the pad 102 through the CuN layer 105 and Cu layer 106.

The wiring 109 is provided on the Cu layer 106 that is situated at a position spaced from the wiring pattern 108. As the material of the wiring 109, there can be used, for example, copper (Cu).

FIGS. 2 to 8 are respectively views of steps of manufacturing the conventional wiring substrate. In FIGS. 2 to 8, the same composing portions thereof as the conventional wiring substrate 100 are given the same designations.

Now, description will be given below of the manufacturing method of the conventional wiring substrate 100 with reference to FIGS. 2 to 8. Firstly, in a step shown in FIG. 2, according to a well-known method, on the upper surface 101A of the substrate main body 101, there are formed a pad 102 and an insulating layer 103 having an opening 111.

Next, in a step shown in FIG. 3, according to a spattering method, there is formed a CuN layer 105 in such a manner that it covers the upper surface 103A of the insulating layer 103, such portion of the surface of the insulating layer 103 as constituting the opening 111, and the upper surface of the pad 102.

Next, in a step shown in FIG. 4, according to a spattering method, there is formed a Cu layer 106 in such a manner that it covers the upper surface of the CuN layer 105. Then, in a step shown in FIG. 5, on the upper surface of the Cu layer 106, there is formed a resist membrane 116 having openings 116A and 116B. The opening 116A is formed such that it can expose therefrom such portion of the upper surface of the Cu layer 106 as corresponds to the forming area of the wiring pattern 108. Also, the opening 116B is formed such that it can expose therefrom such portion of the upper surface of the Cu layer 106 as corresponding to the forming area of the wiring 109.

Next, in a step shown in FIG. 6, a plated membrane is deposited and grown on such portions of the upper surface of the Cu layer 106 as respectively exposed from the openings 116A and 116B according to an electrolytic plating method using the Cu layer 106 as a power supply layer, thereby forming the wiring pattern 108 and wiring 109. In this stage, the wiring pattern 108 and wiring 109 are electrically connected to each other through the CuN layer 105 and Cu layer 106.

Next, in a step shown in FIG. 7, there is removed the resist membrane 116 shown in FIG. 6. Then, in a step shown in FIG. 8, according to a wet etching method using an etching solution for Cu (for example, an etching solution containing 5% sulfuric acid and 1.2% hydrogen peroxide water), there are removed the Cu layer 106 and CuN layer 105 simultaneously. The conventional wiring substrate 100 is manufactured in this manner (see, for example, the patent reference 1).

### [Patent Reference 1]

Unexamined Japanese Patent Application Publication No. 2003-218516

However, in the conventional wiring substrate 100, as the bonding layer to be interposed between the insulating layer 103 and seed layer 105, there is used the CuN layer 105 which has a poor bonding characteristic with respect to the insulating layer 103. This raises a problem that the CuN layer 105 can be peeled off from the insulating layer 103.

Here, the peel strength, which is obtained when the CuN layer 105 formed on the insulating layer 103 is tested for its peel strength, is of the order of 0.3 kgf/cm. However, the bonding layer to be formed between the insulating layer 103 and seed layer 105 may preferably have the peel strength of 0.5 kgf/cm or more.

### SUMMARY OF THE INVENTION

The present invention aims at solving the above-mentioned problems found in the conventional wiring substrate. Thus, it is an object of the invention to provide a wiring substrate which can prevent a bonding layer interposed between an insulating layer and a seed layer from peeling off from the insulating layer, and a method for manufacturing such wiring substrate.

According to a first aspect of the invention, there is provided a wiring substrate, including:

an insulating layer;

a wiring;

a bonding layer provided on such portion of the upper surface of the insulating layer as corresponding to the forming area of the wiring; and

a seed layer interposed between the bonding layer and the wiring, wherein

the bonding layer is a Ni—Cu alloy layer, and

the content of Ni contained in the Ni—Cu alloy layer is set in the range of 20 wt %˜75 wt % and a Cu layer is used as the seed layer.

According to the invention, as the bonding layer, which is provided on such portion of the insulating layer as corresponding to the forming area of the wiring and is also interposed between the seed layer and insulating layer, there is used the Ni—Cu alloy layer which has an excellent bonding characteristic with respect to the insulating layer. This makes it possible to prevent the Ni—Cu alloy layer serving as the bonding layer from peeling off from the insulating layer.

According to a second aspect of the invention, there is provided a wiring substrate, including:

an insulating layer having an opening for exposing the upper surface of a pad therefrom;

a wiring pattern including a via to be disposed in the opening and a wiring connected to the via;

a bonding layer provided on such portions of the surface of the insulating layer and the upper surface of the pad as respectively corresponding to the forming area of the wiring pattern; and

a seed layer interposed between the bonding layer and wiring pattern, wherein

the bonding layer is a Ni—Cu alloy layer, and

the content of Ni contained in the Ni—Cu alloy layer is set in the range of 20 wt %˜75 wt % and a Cu layer is used as the seed layer.

According to the present invention, as the bonding layer, which is provided on such portion of the surface of the insulating layer as corresponding to the forming area of the wiring pattern and also on the upper surface of the pad as well as is interposed between the seed layer and insulating layer, there is used the Ni—Cu alloy layer which has an excellent bonding characteristic with respect to the insulating layer. This makes it possible to prevent the Ni—Cu alloy layer serving as the bonding layer from peeling off from the insulating layer.

According to a third aspect of the invention, there is provided a method for manufacturing a wiring substrate including an insulating layer, a wiring, a bonding layer provided on such portion of the upper surface of the insulating layer as corresponding to the forming area of the wiring, and a seed layer interposed between the bonding layer and the wiring,

the method including:

a Ni—Cu alloy layer forming step of forming a Ni—Cu alloy layer serving as the bonding layer in such a manner that the Ni—Cu alloy layer covers the upper surface of the insulating layer;

a seed layer forming step of forming the seed layer in such a manner that the seed layer covers the upper surface of the Ni—Cu alloy layer;

a resist membrane forming step of forming, on the upper surface of the seed layer, a resist membrane having an opening for exposing therefrom such portion of the upper surface of the seed layer as corresponding to the forming area of the wiring;

a wiring forming step of, after the resist membrane forming step, forming the wiring on such portion of the seed layer as exposed from the opening according to an electrolytic plating method using the seed layer as a power supply layer;

a resist membrane removing step of, after the wiring forming step, removing the resist membrane; and

a seed layer and Ni—Cu alloy layer removing step of removing such portions of the seed layer and the Ni—Cu alloy layer as respectively formed in other areas than the forming area of the wiring.

According to the present invention, the Ni—Cu alloy layer serving as the bonding layer is formed in such a manner that it covers the upper surface of the insulating layer, next, the seed layer is formed in such a manner that it covers the upper surface of the Ni—Cu alloy layer, next, on the upper surface of the seed layer, there is formed the resist membrane having the opening for exposing therefrom such portion of the upper surface of the seed layer as corresponding to the forming area of the wiring, after then, the wiring is formed on such portion of the seed layer as exposed from the opening according to an electrolytic plating method using the seed layer as a power supply layer, next, the resist membrane is removed and, after then, there are removed such portions of the seed layer and Ni—Cu alloy layer as respectively formed in other areas than the forming area of the wiring, whereby, between such portion of the seed layer as corresponding to the forming area of the wiring and insulating layer, there can be interposed the Ni—Cu alloy layer as the bonding layer having an excellent bonding characteristic with respect to the insulating layer. This makes it possible to prevent the Ni—Cu alloy layer serving as the bonding layer from peeling off from the insulating layer.

According to a forth aspect of the invention, there is provided a method for manufacturing a wiring substrate including an insulating layer having an opening for exposing the upper surface of a pad therefrom, a wiring pattern including a via to be provided in the opening and a wiring connected to the via, a bonding layer provided on such portions of the surface of the insulating layer as corresponding to the forming area of the wiring pattern and on the upper surface of the pad, and a seed layer interposed between the bonding layer and the wiring pattern,

the method including:

a Ni—Cu alloy layer forming step of forming a Ni—Cu alloy layer serving as the bonding layer in such a manner that the Ni—Cu alloy layer covers the upper surface of the insulating layer, such portion of the surface of the insulating layer as constituting the opening, and the pad;

a seed layer forming step of forming the seed layer in such a manner that the seed layer covers the upper surface of the Ni—Cu alloy layer;

a resist membrane forming step of forming, on the upper surface of the seed layer, a resist membrane having an opening for exposing therefrom such portion of the upper surface of the seed layer as corresponding to the forming area of the wiring pattern;

a wiring pattern forming step of, after the resist membrane forming step, forming the wiring pattern on such portion of the seed layer as exposed from the opening according to an electrolytic plating method using the seed layer as a power supply layer;

a resist membrane removing step of, after the wiring pattern forming step, removing the resist membrane; and

a seed layer and Ni—Cu alloy layer removing step of removing such portions of the seed layer and the Ni—Cu alloy layer as respectively formed in other areas than the forming area of the wiring pattern.

According to a fifth aspect of the invention, there is the wiring substrate manufacturing method as set forth in the third aspect, wherein

in the seed layer forming step, a Cu layer is formed as the seed layer, and

in the Ni—Cu alloy layer forming step, the Ni—Cu alloy layer is formed in such a manner that the content of Ni contained in the Ni—Cu alloy layer is 20 wt %˜75 wt %.

According to a sixth aspect of the invention, there is the wiring substrate manufacturing method as set forth in the third aspect, wherein

in the Ni—Cu alloy layer forming step, the Ni—Cu alloy layer is formed according to a spattering method.

According to a seventh aspect of the invention, there is the wiring substrate manufacturing method as set forth in the forth aspect, wherein

in the seed layer forming step, a Cu layer is formed as the seed layer, and

in the Ni—Cu alloy layer forming step, the Ni—Cu alloy layer is formed in such a manner that the content of Ni contained in the Ni—Cu alloy layer is 20 wt %˜75 wt %.

According to an eighth aspect of the invention, there is the wiring substrate manufacturing method as set forth in the forth aspect, wherein

in the Ni—Cu alloy layer forming step, the Ni—Cu alloy layer is formed according to a spattering method.

According to the present invention, there is formed the Ni—Cu alloy layer serving as the bonding layer in such a manner that it covers the upper surface of the insulating layer, such portion of the surface of the insulating layer as constituting the opening, and the pad; next, there is formed the seed layer in such a manner that it covers the upper surface of the Ni—Cu alloy layer; next, on the upper surface of the seed layer, there is formed the resist membrane having the opening for exposing therefrom such portion of the upper surface of the seed layer as corresponding to the forming area of the wiring pattern; after then, on such portion of the seed layer as exposed from the opening, there is formed the wiring pattern according to an electrolytic plating method using the seed layer as a power supply layer; next, there is removed the resist membrane; and, after then, there are removed such portions of the seed layer and Ni—Cu alloy layer as respectively formed in other areas than the forming area of the wiring pattern, whereby, between such portion of the seed layer as corresponding to the forming area of the wiring pattern and insulating layer, there can be interposed the Ni—Cu alloy layer as the bonding layer having an excellent bonding characteristic with respect to the insulating layer. This makes it possible to prevent the Ni—Cu alloy layer serving as the bonding layer from peeling off from the insulating layer.

According to the invention, it is possible to prevent a bonding layer interposed between a seed layer and an insulating layer from peeling off from the insulating layer.

### BRIEF DESCRIPTION OF THE DRAWINGS

FIG. 1 is a section view of a conventional wiring substrate.

FIG. 2 is a view of a method for manufacturing the conventional wiring substrate (a first step).

FIG. 3 is a view of the method for manufacturing the conventional wiring substrate (a second step).

FIG. 4 is a view of the method for manufacturing the conventional wiring substrate (a third step).

FIG. 5 is a view of the method for manufacturing the conventional wiring substrate (a fourth step).

FIG. 6 is a view of the method for manufacturing the conventional wiring substrate (a fifth step).

FIG. 7 is a view of the method for manufacturing the conventional wiring substrate (a sixth step).

FIG. 8 is a view of the method for manufacturing the conventional wiring substrate (a seventh step).

FIG. 9 is a section view of a wiring substrate according to an embodiment of the invention.

FIG. 10 is a view of the method for manufacturing the wiring substrate according to the embodiment of the invention (a first step).

FIG. 11 is a view of the method for manufacturing the wiring substrate according to the embodiment of the invention (a second step).

FIG. 12 is a view of the method for manufacturing the wiring substrate according to the embodiment of the invention (a third step).

FIG. 13 is a view of the method for manufacturing the wiring substrate according to the embodiment of the invention (a fourth step).

FIG. 14 is a view of the method for manufacturing the wiring substrate according to the embodiment of the invention (a fifth step).

FIG. 15 is a view of the method for manufacturing the wiring substrate according to the embodiment of the invention (a sixth step).

FIG. 16 is a view of the method for manufacturing the wiring substrate according to the embodiment of the invention (a seventh step).

FIG. 17 is a graph showing a relationship between a peel strength of the electrolytic Cu plated wiring layer and an Ni content of the Ni—Cu alloy bonding seed layer.

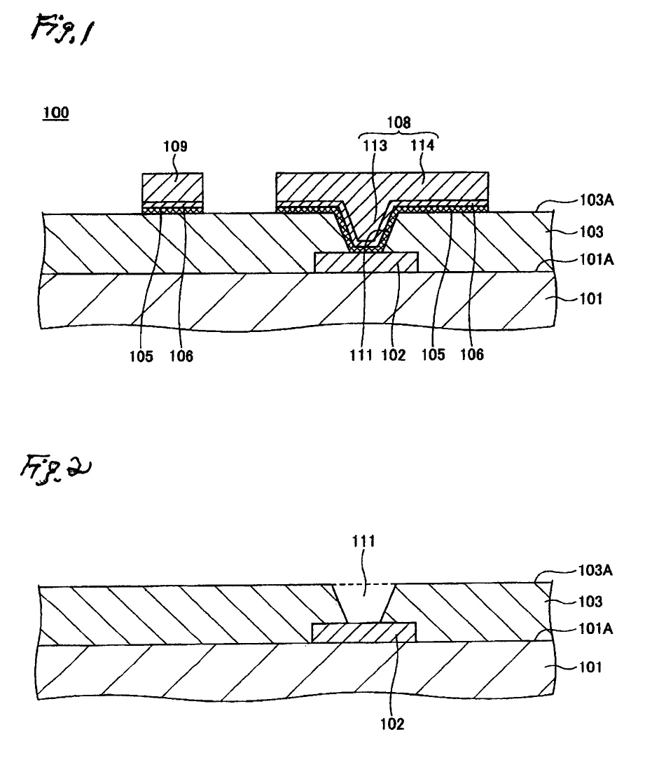

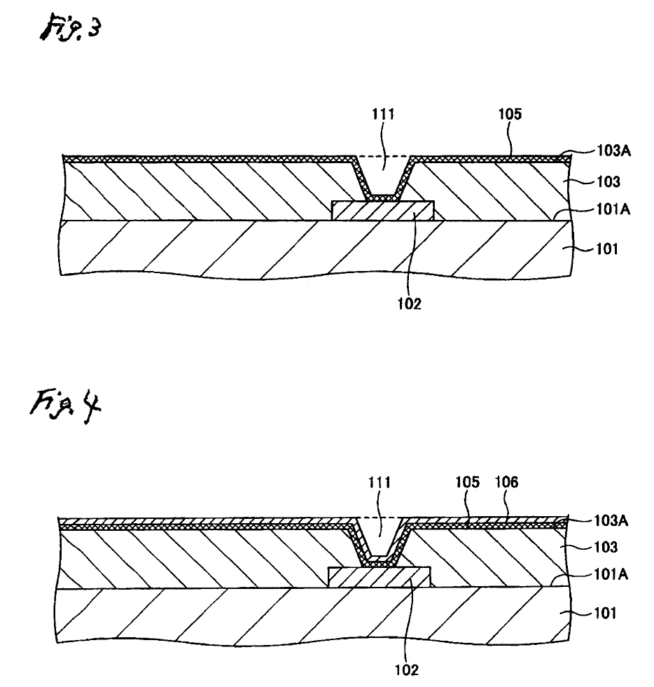

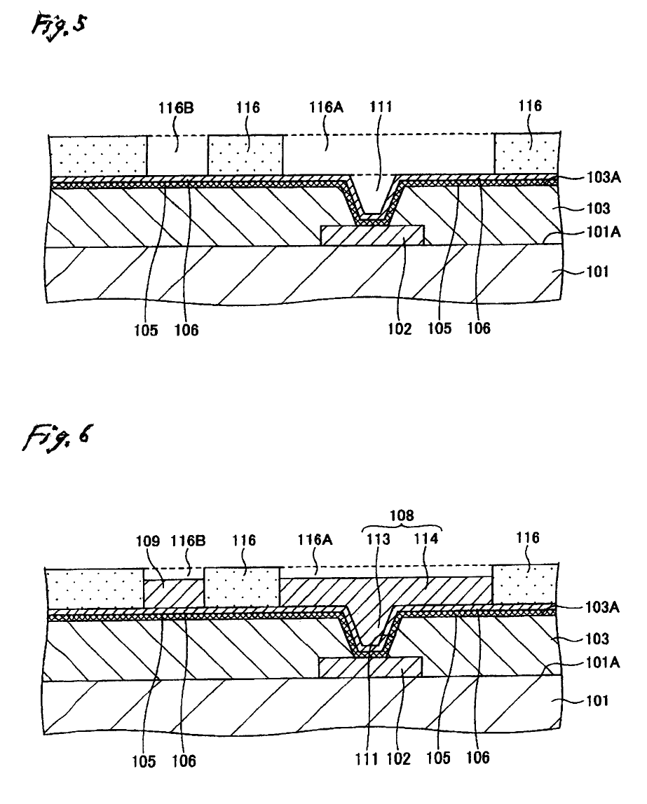

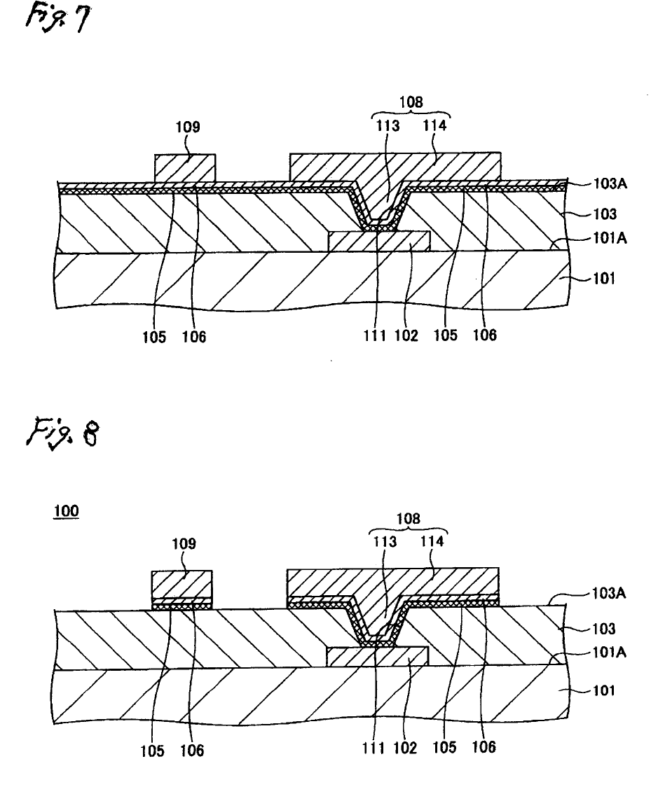

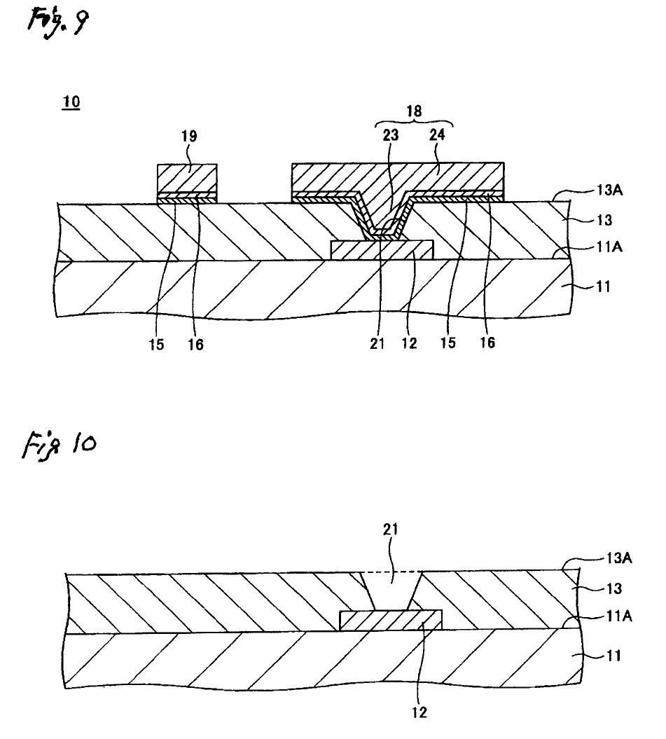

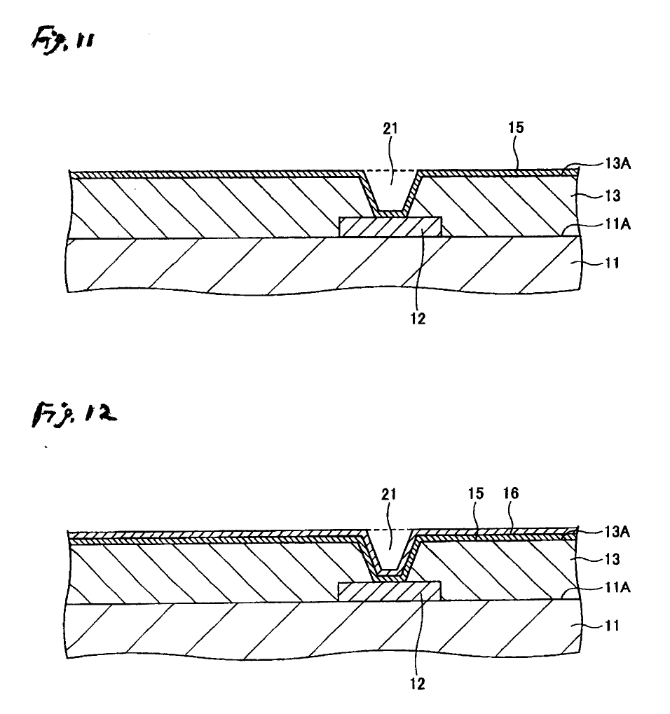

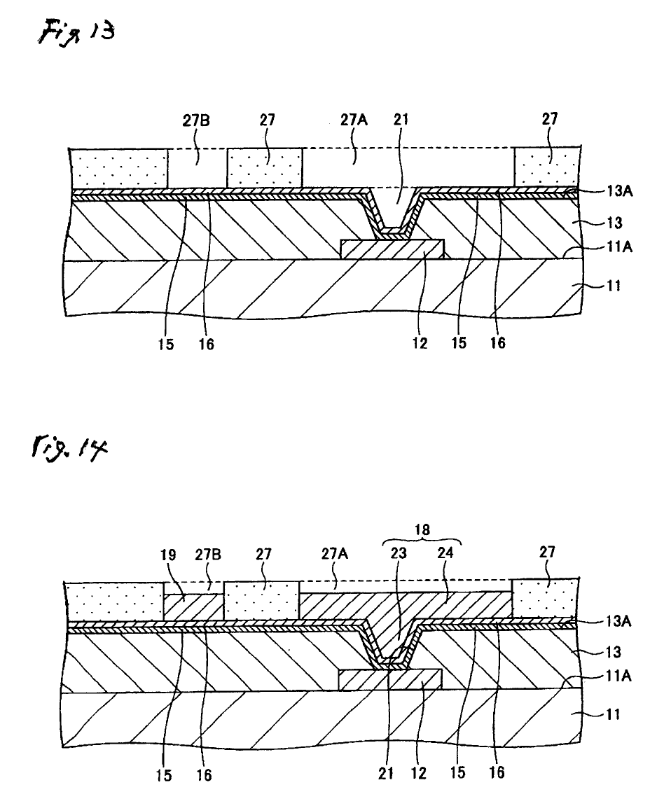

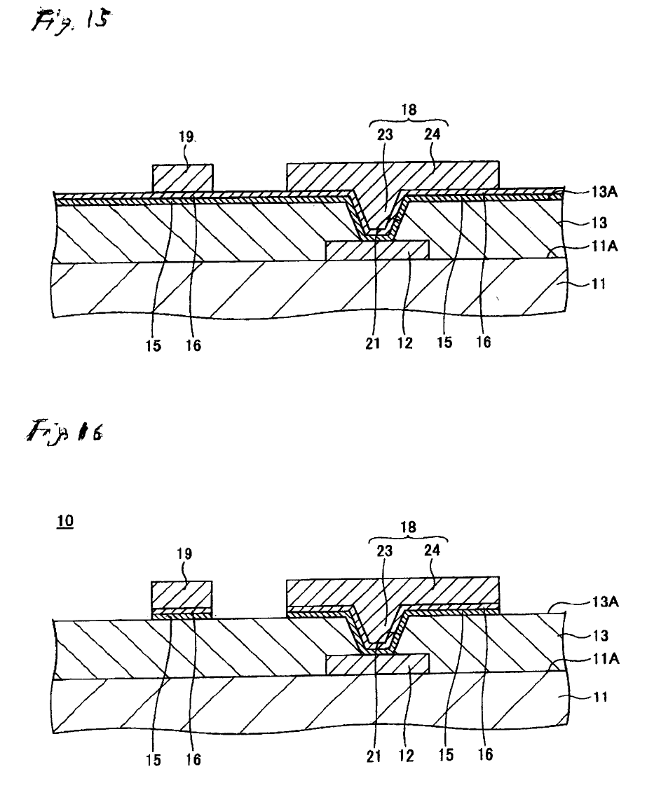

### DETAILED DESCRIPTION OF THE PREFERRED EMBODIMENTS

Next, description will be given below of an embodiment according to the invention with reference to the accompanying drawings.

### Embodiment

FIG. 9 is a section view of a wiring substrate according to the embodiment of the invention.

Referring to FIG. 9, a wiring substrate 10 according to the present embodiment includes a substrate main body 11, a pad 12, an insulating layer 13, a Ni—Cu alloy layer 15, a seed layer 16, a wiring pattern 18, and a wiring 19.

The substrate main body 11 is a substrate on which the pad 12 and insulating layer 13 are to be provided. As the substrate main body 11, there can be used, for example, a build-up substrate with a core or a coreless substrate. The pad 12 is provided on the upper surface 11A of the substrate main body 11. The pad 12 is electrically connected to a wiring and a via (neither of them is shown) which are respectively provided on the substrate main body 11.

The insulating layer 13 is provided on the upper surface 11A of the substrate main body 11 and includes an opening 21 from which the upper surface of the pad 12 can be exposed. The opening 21 is used to provide a via 23 which constitutes the wiring pattern 18. As the insulating layer 13, there can be used, for example, an insulating resin layer. As the material for the insulating resin layer, there can be used, for example, epoxy resin or polyimide resin.

The Ni—Cu alloy layer 15 is provided on such portions of the upper surface 13A of the insulating layer 13 that respectively correspond to the forming areas of the wiring pattern 18 and wiring 19, on such portion of the surface of the insulating layer 13 that constitutes the side surface of the opening 21, and on such portion of the upper surface of the pad 12 that constitutes the bottom surface of the opening 21. The Ni—Cu alloy layer 15 is the bonding layer that is interposed between the insulating layer 13 and seed layer 16.

The content of Ni contained in the Ni—Cu alloy layer 15, preferably, may be, for example, 20 wt % or more. This can enhance the bonding characteristic between the Ni—Cu alloy layer 15 and insulating layer 13. Specifically, the peel strength of the Ni—Cu alloy layer 15 provided on the insulating layer 13 can be set 0.5 kgf/cm or more. Here, when the content of Ni contained in the Ni—Cu alloy layer 15 is less than 20 wt %, the peel strength of the Ni—Cu alloy layer 15 provided on the insulating layer 13 is less than 0.5 kgf/cm, so that the Ni—Cu alloy layer 15 is not be able to fulfill its function as the bonding layer.

In this manner, since, as a bonding layer to be interposed between the insulating layer 13 and seed layer 16, there is used the Ni—Cu alloy layer 15 with the content of Ni equal to or higher than 20 wt %, the bonding characteristic between the insulating layer 13 and Ni—Cu alloy layer 15 can be enhanced, thereby being able to prevent the Ni—Cu alloy layer 15 serving as a bonding layer from peeling off from the insulating layer 13.

Also, the content of Ni contained in the Ni—Cu alloy layer 15, preferably, may be set, for example, in the range of 20 wt %˜75 wt %.

FIG. 17 shows a relationship between an Ni content of the Ni—Cu alloy film and a peel strength. A state in an Ni content of 100 wt % shown on a right end of FIG. 17 corresponds to the peel strength in case of Ni bonding layer/Cu seed layer.

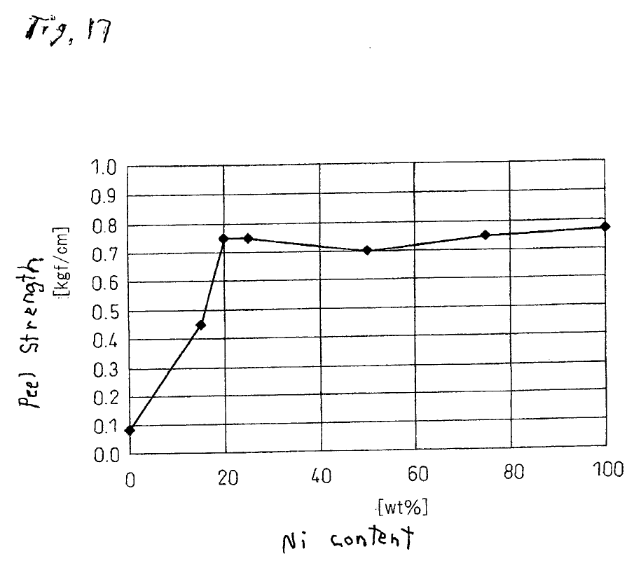

In this manner, when the content of Ni contained in the Ni—Cu alloy layer 15 is set in the range of 20 wt %˜75 wt %, not only the Ni—Cu alloy layer 15 serving as a bonding layer can be prevented from peeling off from the insulating layer 13 but also, for example, using an etching solution for Cu (for example, a sulfate system aqueous solution) used to remove the unnecessary portion of the seed layer 16 when a Cu layer is used as the seed layer 16 (see FIG. 16), there can be removed the Ni—Cu alloy layer 15.

Here, when the content of Ni contained in the Ni—Cu alloy layer 15 exceeds 75 wt %, it is difficult to remove the Ni—Cu alloy layer 15 using the Cu etching solution. When the content of Ni contained in the Ni—Cu alloy layer 15 is set in the range of 20 wt %˜75 wt %, the thickness of the Ni—Cu alloy layer 15 can be set, for example, in the range of 30 nm˜100 nm.

The seed layer 16 is disposed in such a manner that it covers the upper surface of the Ni—Cu alloy layer 15. The seed layer 16 is a power supply layer which is used when forming the wiring pattern 18 and wiring 19 according to an electrolytic plating method. As the seed layer 16, for example, there can be used a Cu layer. When the Cu layer is used as the seed layer 16, the thickness of the seed layer 16 can be set, for example, in the range of 300 nm˜500 nm.

The wiring pattern 18 includes a via 23 and a wiring 24 formed integrally with the upper portion of the via 23. The via 23 is provided on the seed layer 16 disposed in an opening 21. The wiring 24 is provided on the via 23 and seed layer 16. As the material of the wiring pattern 18, there can be used, for example, Cu. The wiring pattern 18 having the above structure is electrically connected to the pad 21 through the Ni—Cu alloy layer 15 and Cu layer 16.

The wiring 19 is provided on the upper surface of the Cu layer 16 disposed at a position spaced from the wiring pattern 18. As the material of the wiring 19, for example, there can be used copper (Cu).

According to the wiring substrate of the present embodiment, since, as a bonding layer to be interposed between the insulating layer 13 and seed layer 16, there is used the Ni—Cu alloy layer 15 containing Ni the contents of which is 20 wt % or more, the bonding characteristic between the insulating layer 13 and Ni—Cu alloy layer 15 can be enhanced. This makes it possible to prevent the Ni—Cu alloy layer serving as the bonding layer from peeling off from the insulating layer 13.

Also, since the content of Ni contained in the Ni—Cu alloy layer 15 is set in the range of 20 wt %˜75 wt %, the Ni—Cu alloy layer serving as the bonding layer can be prevented from peeling off from the insulating layer 13 and, at the same time, for example, using an etching solution for Cu (for example, a sulfate system aqueous solution) which is used to remove the unnecessary portion of the seed layer 16 when a Cu layer is used as the seed layer 16 (see FIG. 16), there can be removed the Ni—Cu alloy layer 15.

FIGS. 10 to 16 are respectively views of steps of manufacturing a wiring substrate according to an embodiment of the invention. In FIGS. 10 to 16, the same composing portions as those of the wiring substrate 10 according to the embodiment of the invention are given the same designations.

Referring to FIGS. 10 to 16, description will be given below of a method for manufacturing the wiring substrate 10 according to the present embodiment. Firstly, in a step shown in FIG. 10, according to a well-known technique, on the upper surface 11A of the substrate main body 11, there are formed a pad 12 and an insulating layer 13 having an opening 21 in this order sequentially. After then, using an Ar plasma, there is purified (there is removed the moisture content of) the upper surface 13A and opening 21 of the insulating layer 13.

As the substrate main body 11, for example, there can be used a substrate such as a build-up substrate with a core or a coreless substrate. The pad 12 can be formed according to, for example, a subtractive method or a semi-additive method. Also, as the material of the pad 12, there can be used, for example, copper (Cu). To form the insulating layer 13, for example, a semi-hardened insulating resin sheet made of epoxy resin, polyimide resin or the like may be bonded to the upper surface 11A of the substrate main body 11 with the pad formed thereon and the semi-hardened insulating resin sheet may be then hardened. The opening 21 may be formed according to, for example, a laser working method.

Next, in a step shown in FIG. 11, there is formed a Ni—Cu alloy layer 15 including Ni the content of which is 20% or more in such a manner that it covers the upper surface 13A of the insulating layer 13, such portion of the surface of the insulating layer 13 as constituting the opening 21, and the upper surface of the pad 12 (the step of forming a Ni—Cu alloy layer).

In this manner, since, as the bonding layer to be interposed between the insulating layer 13 and seed layer 16, there is formed a Ni—Cu alloy layer 15 containing Ni having a content of 20 wt % or more, the bonding characteristic between the insulating layer 13 and Ni—Cu alloy layer 15 is enhanced (specifically, the peel strength of Ni—Cu alloy layer 15 is 0.5 kgf/cm or more). This makes it possible to prevent the Ni—Cu alloy layer 15 serving as the bonding layer from peeling off from the insulating layer 13.

Also, preferably, the content of Ni contained in the Ni—Cu alloy layer 15 may be set, for example, in the range of 20 wt %˜75 wt %.

In this manner, when the content of Ni contained in the Ni—Cu alloy layer 15 is set in the range of 20 wt %˜75 wt %, the Ni—Cu alloy layer 15 serving as the bonding layer can be prevented from peeling off from the insulating layer 13; and, at the same time, for example, when a Cu layer is used as the seed layer 16, in a step shown in FIG. 16 (which will be discussed later), using a Cu etching solution (for example, a sulfate system aqueous solution) which is used to remove the unnecessary portion of the seed layer 16, there can be removed the unnecessary portions of the seed layer 16 (the portions of the seed layer 16 that are formed in the other areas than the forming areas of the wiring pattern 18 and wiring 19) as well as the unnecessary portions of the Ni—Cu alloy layer 15 (the portions of the Ni—Cu alloy layer 15 that are formed in the other areas than the forming areas of the wiring pattern 18 and wiring 19). This eliminates the need to remove the unnecessary portions of the seed layer 16 and the unnecessary portions of the Ni—Cu alloy layer 15 using separate etching solutions, thereby being able to prevent the manufacturing cost of the wiring substrate 10 from increasing.

When the content of Ni contained in the Ni—Cu alloy layer 15 is set in the range of 20 wt %˜75 wt %, the thickness of the Ni—Cu alloy layer 15 can be set, for example, in the range of 30 nm˜100 nm.

Also, the Ni—Cu alloy layer 15 maybe formed, for example, according to a spattering method. In this manner, by forming the Ni—Cu alloy layer 15 using the spattering method, the Ni—Cu alloy layer 15 can be formed with high precision in such a manner that the content of Ni contained in the Ni—Cu alloy layer 15 can provide a desired rate.

Next, in a step shown in FIG. 12, the seed layer 16 is formed in such a manner that it covers the upper surface of the Ni—Cu alloy layer 15 (seed layer forming step). The seed layer 16 may be formed, for example, according to a spattering method.

In this manner, by forming the seed layer 16 using the spattering method, the seed layer 16 can be formed using a spattering device which is used when forming the Ni—Cu alloy layer 15.

As the seed layer 16, for example, there can be used a Cu layer. When a Cu layer is used as the seed layer 16, the thickness of the seed layer 16 can be set, for example, in the range of 300 nm˜500 nm.

Next, in a step shown in FIG. 13, on the upper surface of the seed layer 16, there is formed a resist membrane 27 which includes openings 27A and 27B (resist membrane forming step). The opening 27A is formed such that such portion of the upper surface of the seed layer 16 as corresponds to the forming area of the wiring pattern 18 can be exposed from the opening 27A. Also, the opening 27B is formed such that such portion of the upper surface of the seed layer 16 as corresponds to the forming area of the wiring 19 can be exposed from the opening 27B.

Next, in a step shown in FIG. 14, according to an electrolytic plating method using the seed layer 16 as a power supply layer, a plated membrane (for example, a Cu plated membrane) is deposited and grown on such portions of the seed layer 16 as respectively exposed from the openings 27A and 27B, whereby there are formed not only a wiring pattern 18 including a via 23 and a wiring 24 but also a wiring 19 simultaneously (wiring pattern forming step and wiring forming step). In this stage, the wiring pattern 18 is electrically connected to the wiring 19 through the Ni—Cu alloy layer 15 and seed layer 16. The thickness of the wirings 19 and 24 can be set, for example, 20 μm.

Next, in a step shown in FIG. 15, there is removed the resist membrane 27 shown in FIG. 14 (resist membrane removing step). Next, in a step shown in FIG. 16, there are removed such portions of the seed layer 16 and Ni—Cu alloy layer 15 as formed in the other areas than the forming areas of the wiring pattern 18 and wiring 19 (that is, the unnecessary portions of the seed layer 16 and Ni—Cu alloy layer 15) (seed layer and Ni—Cu alloy layer removing step).

Specifically, when a Cu layer is used as the seed layer 16 and the content of Ni contained in the Ni-cu alloy layer 15 is set in the range of 20 wt %˜75 wt %, the unnecessary portions of the seed layer 16 and Ni—Cu alloy layer 15 are removed simultaneously using a Cu etching solution (for example, a sulfate system aqueous solution). That is, the wiring substrate 10 according to the present embodiment can be manufactured in this manner.

According to the wiring substrate manufacturing method of the present embodiment, since, as the bonding layer to be interposed between the insulating layer 13 and seed layer 16, there is formed the Ni—Cu alloy layer 15 including Ni having a content of 20 wt % or more, it is possible to enhance the bonding characteristic between the insulating layer 13 and Ni—Cu alloy layer 15 (specifically, the peel strength of the Ni—Cu alloy layer 15 provides 0.5 kgf/cm or more). Thanks to this, the Ni—Cu alloy layer 15 serving as the bonding layer can be prevented from peeling off from the insulating layer 13.

Also, since the content of Ni contained in the Ni—Cu alloy layer 15 is set in the range of 20 wt %˜75 wt %, for example, when a Cu layer is used as the seed layer 16, the unnecessary portion of the seed layer 16 and the unnecessary portion of the Ni—Cu alloy layer 15 can be removed in the same step using the Cu etching solution which is used to remove the unnecessary portion of the seed layer 16. This makes it possible to prevent the manufacturing cost of the wiring substrate 10 from increasing.

As a result that a Cu layer is formed on a Ni—Cu alloy layer, bonding characteristic between an insulating layer and a seed layer is enhanced.

Although description has been given heretofore in detail of the preferred embodiment of the invention, the invention is not limited to such specific embodiment but there are possible various changes and modifications without departing from the range of the subject matter of the invention as set forth in the scope of the appended patent claims.

The invention can apply to a wiring substrate including a bonding layer interposed between a seed layer and an insulating layer and also to a method for manufacturing such wiring substrate.

What is claimed is:

1. A wiring substrate, comprising:
an insulating layer;
a wiring;
a bonding layer provided on such portion of the upper surface of the insulating layer as corresponding to the forming area of the wiring; and
a seed layer interposed between the bonding layer and the wiring, wherein
the bonding layer is a Ni—Cu alloy layer, and
the content of Ni contained in the Ni—Cu alloy layer is set in the range of 20 wt %˜75 wt % and a Cu layer is used as the seed layer.

2. A wiring substrate, comprising:
an insulating layer having an opening for exposing the upper surface of a pad therefrom;
a wiring pattern including a via to be disposed in the opening and a wiring connected to the via;
a bonding layer provided on such portions of the surface of the insulating layer and the upper surface of the pad as respectively corresponding to the forming area of the wiring pattern; and
a seed layer interposed between the bonding layer and the wiring pattern, wherein
the bonding layer is a Ni—Cu alloy layer, and
the content of Ni contained in the Ni—Cu alloy layer is set in the range of 20 wt %˜75 wt % and a Cu layer is used as the seed layer.

3. A method for manufacturing a wiring substrate comprising an insulating layer, a wiring, a bonding layer provided on such portion of the upper surface of the insulating layer as corresponding to the forming area of the wiring, and a seed layer interposed between the bonding layer and the wiring,
the method comprising:
a Ni—Cu alloy layer forming step of forming a Ni—Cu alloy layer serving as the bonding layer in such a manner that the Ni—Cu alloy layer covers the upper surface of the insulating layer;
a seed layer forming step of forming a seed layer in such a manner that the seed layer covers the upper surface of the Ni—Cu alloy layer;
a resist membrane forming step of forming, on the upper surface of the seed layer, a resist membrane having an opening for exposing therefrom such portion of the upper surface of the seed layer as corresponding to the forming area of the wiring;
a wiring forming step of, after the resist membrane forming step, forming the wiring on such portion of the seed layer as exposed from the opening according to an electrolytic plating method using the seed layer as a power supply layer;
a resist membrane removing step of, after the wiring forming step, removing the resist membrane; and
a seed layer and Ni—Cu alloy layer removing step of removing such portions of the seed layer and the Ni—Cu alloy layer as respectively formed in other areas than the forming area of the wiring.

4. A method for manufacturing a wiring substrate comprising an insulating layer having an opening for exposing the upper surface of a pad therefrom, a wiring pattern including a via to be provided in the opening and a wiring connected to the via, a bonding layer provided on such portion of the surface of the insulating layer as corresponding to the forming area of the wiring pattern and on the upper surface of the pad, and a seed layer interposed between the bonding layer and the wiring pattern,
the method comprising:
a Ni—Cu alloy layer forming step of forming a Ni—Cu alloy layer serving as the bonding layer in such a manner that the Ni—Cu alloy layer covers the upper surface of the insulating layer, such portion of the surface of the insulating layer as constituting the opening, and the pad;
a seed layer forming step of forming a seed layer in such a manner that the seed layer covers the upper surface of the Ni—Cu alloy layer;
a resist membrane forming step of forming, on the upper surface of the seed layer, a resist membrane having an opening for exposing therefrom such portion of the upper surface of the seed layer as corresponding to the forming area of the wiring pattern;
a wiring pattern forming step of, after the resist membrane forming step, forming the wiring pattern on such portion of the seed layer as exposed from the opening according to an electrolytic plating method using the seed layer as a power supply layer;
a resist membrane removing step of, after the wiring pattern forming step, removing the resist membrane; and
a seed layer and Ni—Cu alloy layer removing step of removing such portions of the seed layer and the Ni—Cu alloy layer as respectively formed in other areas than the forming area of the wiring pattern.

5. The wiring substrate manufacturing method as set forth in claim 3, wherein
in the seed layer forming step, a Cu layer is formed as the seed layer, and
in the Ni—Cu alloy layer forming step, the Ni—Cu alloy layer is formed in such a manner that the content of Ni contained in the Ni—Cu alloy layer is 20 wt %˜75 wt %.

6. The wiring substrate manufacturing method as set forth in claim 3, wherein
in the Ni—Cu alloy layer forming step, the Ni—Cu alloy layer is formed according to a spattering method.

7. The wiring substrate manufacturing method as set forth in claim 4, wherein
in the seed layer forming step, a Cu layer is formed as the seed layer, and
in the Ni—Cu alloy layer forming step, the Ni—Cu alloy layer is formed in such a manner that the content of Ni contained in the Ni—Cu alloy layer is 20 wt %˜75 wt %.

8. The wiring substrate manufacturing method as set forth in claim 4, wherein
in the Ni—Cu alloy layer forming step, the Ni—Cu alloy layer is formed according to a spattering method.
